(19) United States
(12) Patent Application Publication
(10) Pub. No.: US 2024/0036119 A1
(43) Pub. Date: Feb. 1, 2024

(54) BATTERY LIFE PREDICTION DEVICE AND OPERATING METHOD THEREOF

(71) Applicant: SAMSUNG ELECTRONICS CO., LTD., Suwon-si (KR)

(72) Inventors: KYUTAE KIM, Suwon-si (KR); SungHyun YOON, Suwon-si (KR); JONGHOON KIM, Daejeon (KR); SANGUK KWON, Daejeon (KR); JEONGHO AHN, Daejeon (KR)

(73) Assignees: SAMSUNG ELECTRONICS CO., LTD., Suwon-si (KR); The Industry & Academic Cooperation in Chungnam National University (IAC), Daejeon (KR)

(21) Appl. No.: 18/206,347

(22) Filed: Jun. 6, 2023

(30) Foreign Application Priority Data
Jul. 29, 2022 (KR) 10-2022-0095074

(51) Int. Cl. G01R 31/392; G01R 31/367

(52) U.S. Cl. CPC G01R 31/392; G01R 31/367

(57) ABSTRACT

A battery life prediction device, including a state data generator configured to receive information about a battery in real time and to generate state-of-health data; a state data storage configured to store the state-of-health data and past state data; and a battery life calculator configured to: generate a health state model based on the past state data, generate state prediction data based on the state-of-health data using the health state model, determine whether to modify the health state model based on the state prediction data and the state-of-health data, and calculate a remaining life of the battery, wherein the generating of the health state model includes generating an initial model including a non-linear function, determining an initial model coefficient using a least squares approximation based on the past state data, and generating the health state model based on the initial model coefficient and the initial model

### CROSS-REFERENCE TO RELATED APPLICATIONS

This application claims priority under 35 U.S.C. § 119 to Korean Patent Application No. 10-2022-0095074 filed on Jul. 29, 2022, in the Korean Intellectual Property Office, the disclosures of which is incorporated by reference herein in its entirety.

### BACKGROUND

### 1. Field

The present disclosure relates to a battery life prediction device and an operating method thereof, and more particularly, to a device and a method for predicting a remaining life of a battery based on a historical state of the battery measured in real time.

### 2. Description of Related Art

When the grid-based power supply is interrupted in situations which require a constant power supply, such as a semiconductor factory or a nuclear power plant, significant human and economic losses may occur. To prevent this, an uninterruptible power supply system (UPS) may be used to supply emergency power instead of the main power in an emergency situation such as loss of the main power. A lithium-ion battery may be used as the energy source of the uninterruptible power supply system. The stability of the power from the UPS may also be considered important to supply the power stably, and accurate prediction of the remaining life of the lithium-ion battery may be beneficial to ensure the reliability and safety of the power supply.

In some methods for remaining battery life prediction, a battery manufacturer may conduct an aging test in advance, and provide the user with the aging data accumulated during the experiment, and the user may predict the remaining life state in the future based on the battery usage time. However, because the aging trend of the battery may vary depending on the tolerance occurring at the time of manufacture, the operating pattern such as charging and discharging of the battery, and the external environment condition, these methods may have a limitation in reflecting the above external factors of the battery.

Due to the limitations of these and other methods, there is the possibility that an error occurs between the predicted life and the actual lifespan, thereby causing a decrease in the reliability of the system and the economic loss due to a power supply problem of the UPS.

### SUMMARY

Provided is a device for predicting a remaining life of a battery according to a current battery state more accurately.

Also provided is a method for predicting a remaining life of a battery according to a current battery state more accurately.

In accordance with an aspect of the disclosure, a battery life prediction device includes a state data generator configured to receive information about a battery in real time and to generate state-of-health data; a state data storage configured to store the state-of-health data generated by the state data generator, and to store past state data which is generated based on the state-of-health data; and a battery life calculator configured to: generate a health state model including a formula which indicates an aging trend of the battery based on the past state data, generate state prediction data based on the state-of-health data generated by the state data generator using the health state model, determine whether to modify the health state model based on the state prediction data and the state-of-health data, and calculate a remaining life of the battery, wherein to generate the health state model, the battery life calculator is further configured to: generate an initial model including a non-linear function which includes a model coefficient, determine an initial model coefficient by correcting the model coefficient using a least squares approximation based on the initial model and the past state data, and generate the health state model based on the initial model coefficient and the initial model.

In accordance with an aspect of the disclosure, a method of predicting a battery life includes collecting information about a battery in real time to generate state-of-health data; generating past state data by storing the state-of-health data; generating a health state model including a formula which indicates an aging trend of the battery based on the past state data; generating state prediction data based on the state-of-health data using the health state model; determining whether to modify the health state model based on the state prediction data and the state-of-health data; and calculating a remaining life of the battery based on the state prediction data.

In accordance with an aspect of the disclosure, a battery life prediction system includes a battery including a battery pack; a data measurement unit configured to measure information about the battery, and to generate sensing data including output voltage data and output current data; and a battery life prediction device configured to generate state prediction data based on the sensing data, and to calculate a remaining life of the battery, wherein the battery life prediction device includes: a state data generator configured to receive the sensing data in real time and to generate state-of-health data; a state data store unit configured to store the state-of-health data generated by the state data generator and to generate past state data; and a battery life calculator configured to: generate a health state model indicating an aging trend of the battery in a formula type based on the past state data, generate the state prediction data based on the state-of-health data generated by the state data generator by using the health state model, determine whether to regenerate the health state model based on the state prediction data and the state-of-health data, and calculate the remaining life of the battery, wherein to generate the health state model, the battery life calculator is further configured to: generate an initial model including a non-linear function which includes a model coefficient; and determine an initial model coefficient by correcting the model coefficient using a least squares approximation based on the initial model and the past state data; and generate the health state model based on the initial model coefficient and the initial model.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating a battery life prediction system according to an embodiment of the present disclosure.

FIG. 2 is a block diagram illustrating an example of a battery life prediction device of FIG. 1, according to an embodiment of the present disclosure.

FIG. 3 is a diagram for describing examples of state-of-charge data, state-of-health data, and a battery cycle, according to an embodiment of the present disclosure.

FIG. 4 is a block diagram illustrating an example of a state data generator of FIG. 2, according to an embodiment of the present disclosure.

FIG. 5 is a diagram illustrating an example of an electrical equivalent circuit model of a battery, according to an embodiment of the present disclosure.

FIG. 6 is a block diagram illustrating an example of a dual extended Kalman filter applied to a state data generator of FIG. 4, according to an embodiment of the present disclosure.

FIG. 7 is a block diagram illustrating an example of a battery life calculator of FIG. 2, according to an embodiment of the present disclosure.

FIG. 8 is a flowchart for describing an operating method of a battery life calculator of FIG. 7, according to an embodiment of the present disclosure.

FIG. 9 is a diagram for describing an operation of a particle filter, according to an embodiment of the present disclosure.

FIG. 10 is a diagram illustrating a prior particle distribution and a posterior particle distribution in an operation of a particle filter, according to an embodiment of the present disclosure.

FIGS. 11 and 12 are graphs illustrating a health state model generated by a battery life calculator, a median of state prediction data, a confidence interval, and state-of-health data generated in real time, according to embodiments of the present disclosure.

FIG. 13 is a block diagram illustrating an example in which a risk evaluation device is applied an uninterruptible power supply system, according to an embodiment of the present disclosure.

### DETAILED DESCRIPTION

Below, embodiments of the present disclosure are described in detail with reference to the accompanying drawings.

As is traditional in the field, embodiments may be described and illustrated in terms of blocks which carry out a described function or functions. These blocks, as shown in the drawings, which may be referred to herein as “units” or “modules” or the like, or by names such as device, generator, calculator, corrector, updater, estimator, rectifier, converter, chopper, or the like, may be physically implemented by analog or digital circuits such as logic gates, integrated circuits, microprocessors, microcontrollers, memory circuits, passive electronic components, active electronic components, optical components, hardwired circuits, or the like, and may be driven by firmware and software. The circuits may, for example, be embodied in one or more semiconductor chips, or on substrate supports such as printed circuit boards and the like. Circuits included in a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks. Likewise, the blocks of the embodiments may be physically combined into more complex blocks.

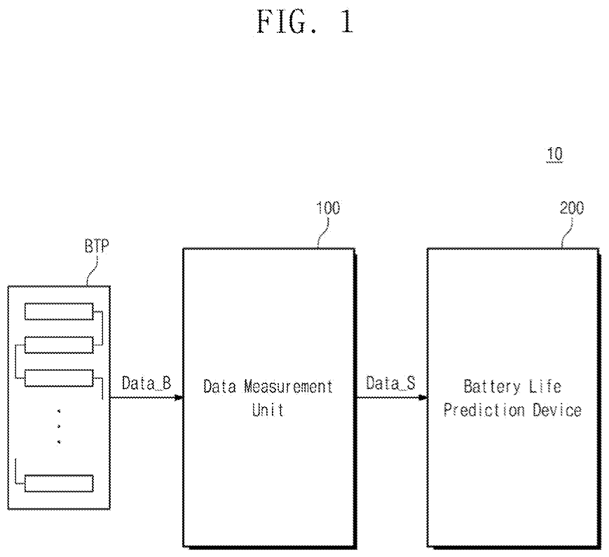

FIG. 1 is a block diagram illustrating a battery life prediction system according to an embodiment of the present disclosure. Referring to FIG. 1, a battery life prediction device 10 may include a data measurement unit 100 and a battery life prediction device 200.

The data measurement unit 100 may be configured to measure information Data_B about a battery targeted for life prediction and to generate sensing data Data_S. A battery BTP may include a battery pack. The battery pack may include a plurality of battery modules.

As an example, the sensing data Data_S generated by the data measurement unit 100 may include current data which may include current information about the battery and voltage data being voltage information about the battery. The voltage data may be generated by measuring an output voltage of the battery pack. The current data may be generated by measuring a current output from the battery pack.

The data measurement unit 100 may be configured to collect the information Data_B about the battery from the battery BTP in real time and to generate the sensing data Data_S. The sensing data Data_S generated from the data measurement unit 100 in real time may be provided to the battery life prediction device 200.

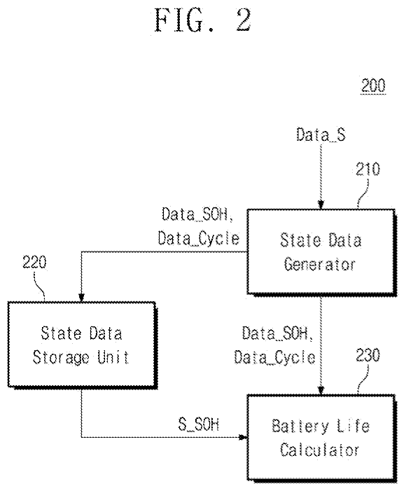

The battery life prediction device 200 may be configured to receive the sensing data Data_S from the data measurement unit 100. The battery life prediction device 200 may be configured to generate state prediction data based on the received sensing data Data_S and to calculate a remaining life of the battery. An example of a configuration and an operation of the battery life prediction device 200 is described in detail below with reference to FIG. 2.

FIG. 2 is a block diagram illustrating an example of the battery life prediction device 200 of FIG. 1, according to embodiments.

Referring to FIG. 2, the battery life prediction device 200 may include a state data generator 210, a state data storage unit 220, and a battery life calculator 230.

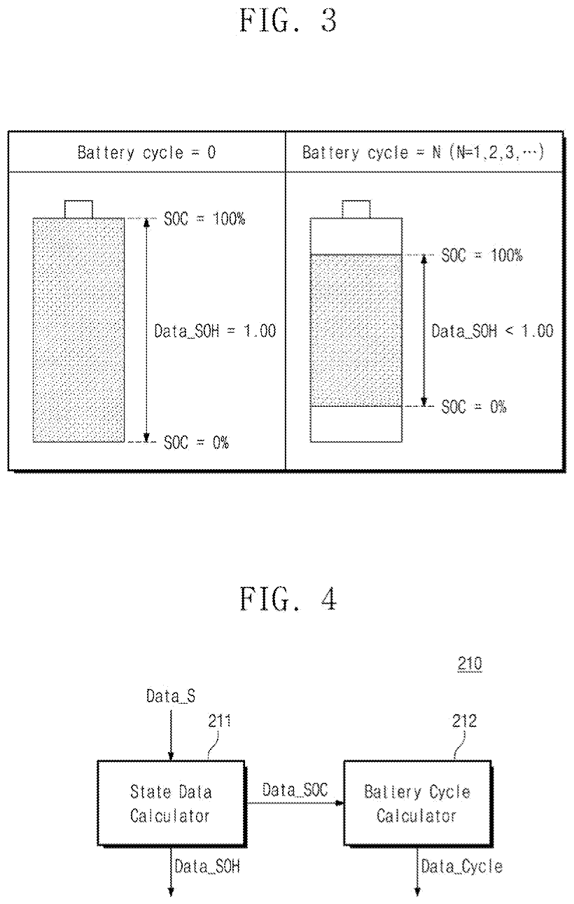

The state data generator 210 may be configured to generate state-of-charge (SOC) data and state-of-health (SOH) data Data_SOH based on the received sensing data Data_S. The state data generator 210 may be configured to generate battery cycle data Data_cycle based on the SOC data. Below, examples of the SOC data, the SOH data Data_SOH, and the battery cycle are described in detail with reference to FIG. 3.

FIG. 3 is a diagram for describing examples of SOC data, SOH data, and a battery cycle, according to embodiments.

Referring to FIG. 3, a value of the battery cycle may increase by an amount of one, for example by being incremented by one, when a battery targeted for measurement is discharged fully (or discharged to less than or equal to a given or predetermined ratio) from a state of being charged fully (or charged to greater than or equal to a given or predetermined ratio) and is again charged fully (or charged to greater than or equal to the or predetermined given ratio). For example, the battery cycle may have a value of two when the battery is again fully charged after being fully discharged from a fully charged state two times. The battery cycle data Data_cycle may include information about the battery cycle.

The SOH may be defined as an available capacity of the battery. The SOH may be defined as an available battery capacity of a current state compared to an initial available capacity of the battery. The initial state may mean a state where the value of the battery cycle is zero. For example, in a state where the value of the battery cycle is zero, the SOH may be 100%, and a value of the SOH data Data_SOH may be 1.0. As the value of the battery cycle increases, the available capacity of the battery may decrease; in this case, the SOH may be determined as a value between 0% and 100%, and a value of the SOH data Data_SOH may be between 0 and 1.0. For example, when the available capacity of the battery is 80% of the initial available capacity, the SOH may be 80%, and a value of the SOH data Data_SOH may be determined as 0.8.

In embodiments, the SOC may be determined as 100% when charges are fully charged as much as a rated capacity of the battery and as 0% when the charges in the battery are fully discharged. For example, the SOC may be determined as a value of 0% to 100% based on the rated capacity of the battery depending on the amount of charges of the battery.

When the value of the battery cycle is zero, the state-of-charge SOC is 100%; in this case, the capacity of the battery and the available capacity of the battery are identical to each other. However, when the value of the battery cycle is not zero, in other words, when the value of the battery cycle is N (where N=1, 2, 3, . . . ), the available capacity of the battery decreases as the battery is aged. In this case, the SOC when the battery is fully charged within the decreased available capacity may be determined as 100%, and the SOC when the battery is fully discharged within the available capacity of the battery may be determined as 0%. For example, when the state-of-charge SOC of the battery is 80% of the available capacity, the SOC may be 80%, and a value of the SOC data may be determined as 0.8.

The SOH may change over a long time relative to the SOC. The SOC may change within a range from 0% to 100% in one battery cycle, but the SOH may decrease smoothly over a plurality of battery cycles. In embodiments, the state of health may be considered to be uniform when measuring the SOC for a specific battery cycle.

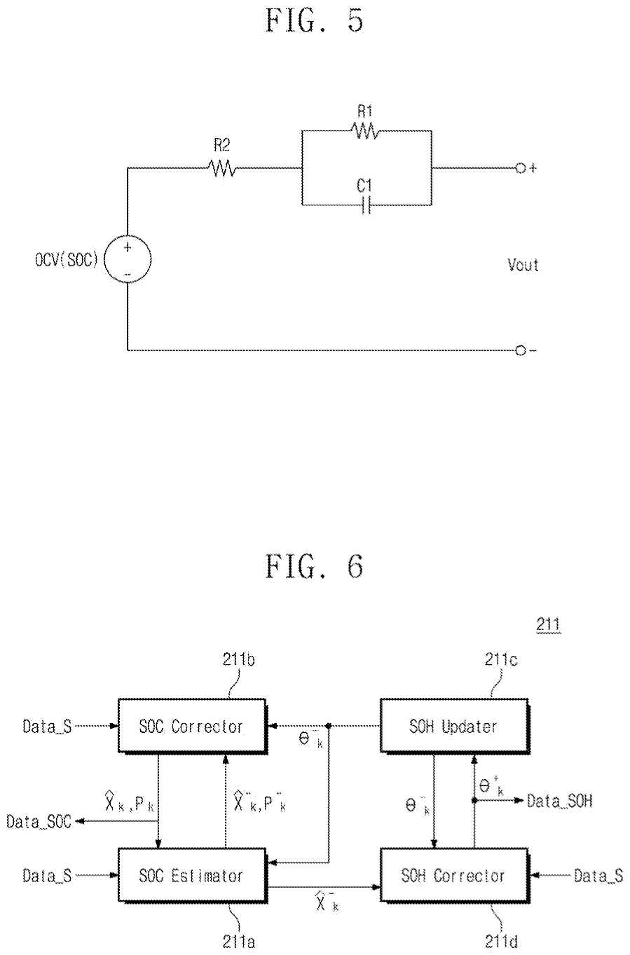

Returning to FIG. 2, the state data generator 210 may be configured to calculate the SOC data and the SOH data Data_SOH of the battery by applying a dual extended Kalman filter to an electrical equivalent circuit model of the battery. An example of how the state data generator 210 generates the SOC data, the SOH data Data_SOH, and the battery cycle data Data_cycle is described in detail below with reference to FIGS. 4 to 6.

The state data storage unit 220 may be configured to store the SOH data Data_SOH and the battery cycle data Data_cycle generated from the state data generator 210. The state data storage unit 220 may sequentially store the SOH data Data_SOH corresponding to each battery cycle to generate past state data S_SOH. The past state data S_SOH may include the SOH data Data_SOH for each of a plurality of battery cycles. The past state data S_SOH stored in the state data storage unit 220 may be provided to the battery life calculator 230.

The battery life calculator 230 may be configured to calculate state prediction data indicating the development of aging of the battery based on the past state data S_SOH. The state prediction data may be calculated in the form of likelihood, for example according to a likelihood function, and the state prediction data may include information about a median and a standard deviation calculated based on the likelihood.

The battery life calculator 230 may be configured to determine whether to regenerate or otherwise modify a health state model, for example by correcting one or more coefficients included in the initial model, based on the state prediction data and the SOH data Data_SOH.

The battery life calculator 230 may be configured to set a confidence interval based on the likelihood of the state prediction data, and to generate a correction signal when the SOH data Data_SOH is not within the confidence interval.

When the correction signal is generated, the battery life calculator 230 may calculate the state prediction data based on the past state data S_SOH which was stored in the state data storage unit 220 before the correction signal was generated.

When the correction signal is not generated, the battery life calculator 230 may be configured to calculate the remaining life of the battery based on the state prediction data. The remaining life of the battery may be an expected amount of time until the available capacity of the battery is reduced from the current available capacity to a given or predetermined available capacity.

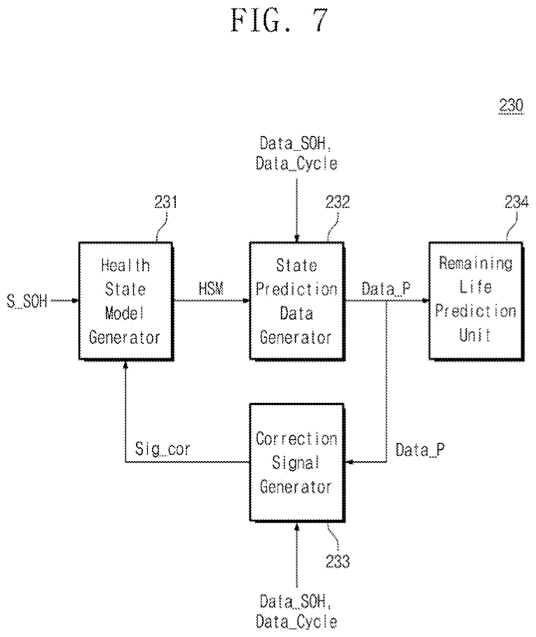

For example, based on an SOH of 80% being set as a critical point, the remaining life of the battery may be determined as an expected number of cycles that until the SOH data Data_SOH reaches 0.8. However, the critical point is not limited thereto. For example, the critical point may be set to a value other than 80%, depending on user requirements. Examples of configuration and operation of the battery life calculator 230 are described in detail below with reference to FIGS. 7 to 12.

FIG. 4 is a block diagram illustrating an example of the state data generator 210 of FIG. 2, according to embodiments. FIG. 5 is a diagram illustrating an example of an electrical equivalent circuit model of a battery, according to embodiments. FIG. 6 is a block diagram illustrating an example of a dual extended Kalman filter applied to the state data generator 210 of FIG. 4, according to embodiments. Below, examples of a configuration and an operation of the state data generator 210 of FIG. 2 are described in detail with reference to FIGS. 4 to 6.

Referring to FIG. 4, the state data generator 210 may include a state data calculator 211 and a battery cycle calculator 212.

The state data calculator 211 may be configured to receive the sensing data Data_S from the data measurement unit 100 and to generate the SOC data Data_SOC and the SOH data Data_SOH.

The state data calculator 211 may be configured to generate the SOC data Data_SOC and the SOH data Data_SOH based on an electrical equivalent circuit model of the battery. For example, the electrical equivalent circuit model of the battery may include a Thevenin electrical equivalent circuit model including an open-circuit voltage (OCV) power, a first internal resistor, a second internal resistor, and a capacitor, as shown for example in FIG. 5.

The state data calculator 211 may be configured to generate SOC data Data_SOC and the SOH data Data_SOH applying the dual extended Kalman filter based on the electrical equivalent circuit model of the battery. Below, an example of a configuration of the state data calculator 211 is described in detail with reference to FIG. 6.

Referring to FIG. 6, the state data calculator 211 may include a dual extended Kalman filter including an SOC estimator 211a, an SOC corrector 211b, an SOH updater 211c, and an SOH corrector 211d. The dual extended Kalman filter may be implemented by combining an extended Kalman filter for calculating the SOC data Data_SOC and an extended Kalman filter for calculating the SOH data Data_SOH in parallel.

The state data calculator 211 may be configured to generate a predicted state-of-charge data by predicting a predicted SOC value of a k-th time point based on the sensing data Data_S of a (k−1)-th time point, and to output corrected data by comparing the sensing data Data_S of the k-th time point and the predicted SOC value. Afterwards, the state data calculator 211 may recurrently perform the operation of outputting the corrected data by predicting data of a (k+1)-th time point by using the corrected data of the k-th time point and comparing a measured SOC value of the (k+1)-th time point with the predicted SOC value of the (k+1)-th time point.

In embodiments, the SOC estimator 211a may receive the sensing data Data_S of the (k−1)-th time point from the data measurement unit 100 and may receive predicted state-of-health data of the (k−1)-th time point from the SOH updater 211c. The SOC estimator 211a may calculate the predicted SOC value of the k-th time point and the predicted SOC error covariance based on the received data.

The calculation of the predicted SOC value, which is performed by the SOC estimator 211a, may be performed based on Equation 1 below. In Equation 1, \hat{x}ₖ⁻ represents the predicted SOC value of the k-th time point, \hat{x}ₖ₋₁ represents the SOC value of the (k−1)-th time point. C₁ represents a value of the capacitor of the Thevenin equivalent circuit of FIG. 5, R₁ represents a first internal resistance value of the Thevenin equivalent circuit of FIG. 5. Q represents an SOC process noise covariance, Qₘₐₓ represents a maximum SOC process noise covariance, and Iₖ represents a measured current data value of the k-th time point included in the sensing data Data_S.

$${\hat{x}}_{k}^{-} = [ \begin{matrix}1 & 0 \\ 0 & 1 - exp ( - \frac{δ t}{{C}_{1} {R}_{1}} )\end{matrix} ] {\hat{x}}_{k - 1} + [ \begin{matrix}- \frac{δ t}{{Q}_{max}} \\ {R}_{1} ( 1 - exp ( - \frac{δ t}{{C}_{1} {R}_{1}} ) )\end{matrix} ] {I}_{k - 1} \qquad [ Equation 1 ]$$

The calculation of the predicted SOC error covariance, which is performed by the SOC estimator 211a, may be performed based on Equation 2 and Equation 3 below. As shown in Equation 2, Pₖ⁻ represents the predicted SOC error covariance of the k-th time point, and Pₖ₋₁ represents the SOC error covariance at the (k−1)-th time point, and A may be determined using Equation 3.

$${P}_{k}^{-} = A {P}_{k - 1} {A}^{T} + Q \qquad [ Equation 2 ]$$

$$A = [ \begin{matrix}1 & 0 \\ 0 & 1 - exp ( - \frac{δ t}{{C}_{1} {R}_{1}} )\end{matrix} ] \qquad [ Equation 3 ]$$

The SOC estimator 211a may transfer the predicted SOC value of the k-th time point to the SOC corrector 211b and the SOH corrector 211d and may transfer the predicted SOC error covariance of the k-th time point to the SOC corrector 211b.

The SOC corrector 211b may receive the sensing data Data_S of the k-th time point from the data measurement unit 100. The SOC corrector 211b may calculate an SOC Kalman gain, state-of-charge data, and a SOC error covariance. The calculation of the SOC Kalman gain, which is performed by the SOC corrector 211b, may be performed based on Equation 4, Equation 5, and Equation 6 below. Kₖ represents the SOC Kalman gain of the k-th time point, R represents a measurement noise, H may be determined using Equation 5, and H^{T} represents a transverse of H.

$${K}_{k} = {P}_{k}^{-} {{H}^{T} ( H {P}_{k}^{-} {H}^{T} + R )}^{- 1} \qquad [ Equation 4 ]$$

$$H = [ \begin{matrix}\frac{δ OCV}{δ SOC} & - 1\end{matrix} ] \qquad [ Equation 5 ]$$

$$OCV = 2.58 SOC + 3.81 {e}^{- 0.84 S O C} - 0.3 {e}^{- 8.3 S O C} \qquad [ Equation 6 ]$$

The calculation of the SOC value, which is performed by the SOC corrector 211b, may be performed depending on Equation 7 below. As shown in Equation 7, \hat{x}ₖ represents the SOC value of the k-th time point, and zₖ represents the sensing data Data_S of the k-th time point.

\hat{x}ₖ=\hat{x}ₖ⁻+Kₖ(zₖ−h(\hat{x}ₖ⁻)) [Equation 7]

The calculation of the SOC error covariance, which is performed by the SOC corrector 211b, may be performed based on Equation 8 below. In Equation 8, Pₖ represents the SOC error covariance of the k-th time point, and H may represent the same variable shown in Equation 4.

Pₖ=Pₖ⁻−KₖHPₖ⁻ [Equation 8]

The SOC data Data_SOC including information about the SOC values calculated by the SOC corrector 211b may be transferred to the battery cycle calculator 212 of FIG. 4. The SOC value and the SOC error covariance of the k-th time point, which are calculated by the SOC corrector 211b, may be transferred to the SOC estimator 211a. Also, the predicted SOH data of the k-th time point output from the SOH updater 211c may be transferred to the SOC estimator 211a and the SOC corrector 211b such that the variables A and Q of Equation 2 may be updated.

The SOH updater 211c may be configured to calculate a predicted SOH value. The predicted SOH value may include a predicted value of the available capacity of the battery, and may be expressed by Equation 9 below.

\hat{θ}ₖ₊₁⁻=\hat{θ}ₖ⁻+w^{θ} [Equation 9]

In Equation 9, \hat{θ}ₖ⁻ represents the predicted SOH value of the k-th time point, \hat{θ}ₖ₊₁⁻ represents the predicted SOH value of the (k+1)-th time point, and w^{θ} represents an input noise.

The calculation of the SOH error covariance, which is performed by the SOH corrector 211d, may be performed depending on Equation 10 below. In Equation 10, Sₖ₊₁⁻ represents the predicted SOH error covariance of the (k+1)-th time point, and Q^{θ} represents an SOH process noise covariance.

Sₖ₊₁⁻=Sₖ⁺+Q^{θ} [Equation 10]

The SOH corrector 211d may combine the error covariance calculated using Equation 10, and Hₖ^{θ} to which an internal characteristic of the battery is applied and may calculate the SOH Kalman gain using Equation 11 below.

Kₖ^{θ}=P_{θ}_{ₖ}⁻(Sₖ^{θ})^{T}[Hₖ^{θ}S_{θ}_{ₖ}⁻(Hₖ^{θ})^{T}+rₖ^{θ}]⁻¹ [Equation 11]

In Equation 11, Kₖ^{θ} represents the SOH Kalman.

The SOH corrector 211d may receive the sensing data Data_S from the data measurement unit 100 and may calculate the SOH value based on Equation 12 below.

\hat{θ}ₖ=\hat{θ}ₖ⁻+Kₖ^{θ}·(Zₖ−\hat{Z}(xₖ,uₖ,θₖ)) [Equation 12]

In Equation 12, \hat{θ}ₖ represents the SOH value of the k-th time point.

The SOH corrector 211d may again transfer the calculated SOH data Data_SOH, which may include information about the determined SOH values, to the SOH updater 211c, and the SOH updater 211c may recurrently perform the operation of calculating the predicted SOH values by using the transferred SOH data Data_SOH as an input.

The SOH corrector 211d may update the SOH error covariance based on the calculated SOH values based on Equation 13 below.

Sₖ₊₁=(I−Kₖ^{θ}Hₖ^{θ})Sₖ⁻ [Equation 13]

In Equation 13, Sₖ₊₁ represents the SOH error covariance of the (k+1)th time point, and Sₖ⁻ represents the predicted SOH error covariance of the k-th time point.

The SOC corrector 211b may calculate the SOC data by adjusting a parameter of the extended Kalman filter based on the predicted SOH values received from the SOH updater 211c, and the SOH corrector 211d may calculate the SOH values based on the sensing data Data_S and predicted SOC data.

The state data calculator 211 may be configured to calculate the SOC data Data_SOC and the SOH data Data_SOH by applying the dual extended Kalman filter based on the predicted SOC data, the predicted SOH data, and the SOC data Data_SOC such that the battery state is applied at a current time point.

Returning to FIG. 4, the battery cycle calculator 212 may be configured to receive the SOC data Data_SOC generated from the state data calculator 211. The battery cycle calculator 212 may be configured to count a battery cycle based on the SOC data Data_SOC and to generate the battery cycle data Data_cycle.

For example, the battery cycle calculator 212 may be configured to calculate the battery cycle data Data_cycle by incrementing the battery cycle by one when the battery is discharged fully (or discharged to less than or equal to the given or predetermined ratio) after being charged fully (or charged to greater than or equal to the given or predetermined ratio).

The SOH data Data_SOH and the battery cycle data Data_cycle generated from the battery cycle calculator 212 may be provided to the state data storage unit 220 of FIG. 2.

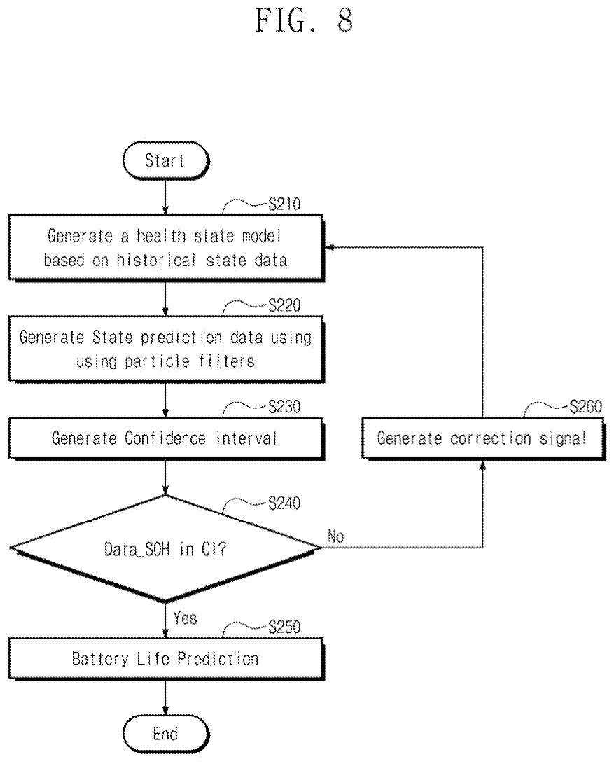

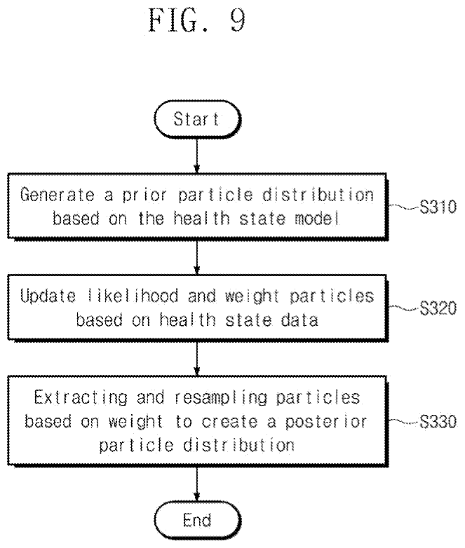

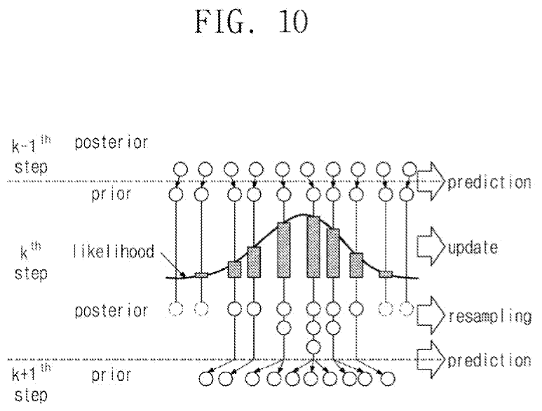

FIG. 7 is a block diagram illustrating an example of a battery life calculator of FIG. 2, according to embodiments. FIG. 8 is a flowchart for describing an operating method of a battery life calculator of FIG. 7, according to embodiments. FIG. 9 is a diagram for describing an operation of a particle filter, according to embodiments. FIG. 10 is a diagram illustrating a prior particle distribution and a posterior particle distribution in an operation of a particle filter, according to embodiments. Below, an example of the battery life calculator 230 is described in detail with reference to FIGS. 7 to 10.

Referring to FIG. 7, the battery life calculator 230 may include a health state model generator 231, a state prediction data generator 232, a correction signal generator 233, and a remaining life prediction unit 234.

The health state model generator 231 may be configured to receive the past state data S_SOH from the state data storage unit 220 and to generate a health state model HSM indicating an estimated value of the SOH of the battery based on the past state data S_SOH.

Referring to FIG. 8, in operation S210, the health state model generator 231 may generate the health state model HSM based on the battery cycle data Data_cycle and the SOH data Data_SOH of the past state data S_SOH.

The past state data S_SOH may include the SOH data Data_SOH associated with the battery cycle data Data_cycle stored in the state data storage unit 220. The health state model HSM that is an experimental model may mean the estimation value of the state of health in the battery cycle.

The health state model generator 231 may be configured to draw an initial model coefficient by setting a non-linear function using the battery cycle data Data_cycle as a variable and including a model coefficient to an initial model and performing a least squares method LSM based on the past state data S_SOH. In embodiments, the least squares method LSM, or a result thereof, may be referred to as a least squares approximation.

The health state model generator 231 may draw the initial model coefficient by correcting the model coefficient such that the sum of the SOH data Data_SOH and the square of the residual of the state-of-health estimation value of the initial model is minimized.

The non-linear function set to the initial model may include a log function, a polynomial function, a gaussian function, etc., and multiple model coefficients may be provided. However, embodiments not limited thereto.

For example, the health state model HSM generated by the health state model generator 231 may be expressed as Equation 14 below.

f(x)=a·exp(−b·x)+c·exp(−d·x)

f(x)=a·exp(−b·x)+c·exp(−d·x) [Equation 14]

In Equation 14, a variable x represents the number of battery cycles, f(x) represents the state-of-health estimation value for the battery cycle, and a, b, c, and d represent initial model coefficients drawn using the least squares method LSM.

The health state model HSM generated by the health state model generator 231 may be provided to the state prediction data generator 232.

The state prediction data generator 232 may be configured to receive the SOH data Data_SOH and the battery cycle data Data_cycle generated by the state data generator 210.

In operation S220, the state prediction data generator 232 may be configured to apply a particle filter to the health state model generated by the health state model generator 231 and to calculate state prediction data Data_P based on the SOH data Data_SOH generated by the state data generator 210.

The particle filter may refer to an algorithm that searches for a prediction value in an arbitrary distribution form to draw a result value. The particle filter may continue to infer the prediction value based on the input measurement values by using the Monte Carlo simulation method, which may be a method appropriate for a non-linear or non-Gaussian system. The particle filter may determine a characteristic of the state variable by calculating a weight, which particles have, based on the Bayesian conditional probabilities such as prior distributions and posterior distributions.

The state prediction data generator 232 may generate the state prediction data Data_P of a likelihood form based on the particle distributions. Below, an example of an operation in which the state prediction data generator 232 generates the state prediction data Data_P based on the particle filter is described in detail with reference to FIG. 9.

In operation S310, the state prediction data generator 232 may generate the prior particle distributions. The prior particle distribution may be generated by substituting the state-of-health estimation value of the health state model into the prior particle distribution of a previous time point. The state prediction data generator 232 may generate the likelihood of the prior predication data based on the prior particle distribution. As the particles become denser in a given area, the probability may become higher in likelihood.

In the case of an initial state (i.e., a first time point), the state prediction data generator 232 may generate a random particle distribution and may then generate the likelihood of the prior prediction data based on the health state model.

In the case of the following state (i.e., a k-th time point, where k is 2, 3, 4, . . . ), the state prediction data generator 232 may generate the prior particle distribution by substituting a state estimation value of the health state model into the posterior particle distribution generated at a previous time point (i.e., a (k−1)-th time point).

In operation S320, the state prediction data generator 232 may be configured to receive the SOH data Data_SOH from the state data generator 210. The state prediction data generator 232 may be configured to update based on the probability that the received SOH data Data_SOH are present in the likelihood of the prior prediction data and may generate the likelihood of the state prediction data Data_P.

The state prediction data generator 232 may assign a weight to the particle of the prior particle distribution based on the updated likelihood. For example, a higher weight may be assigned to a particle included in the area of the updated likelihood, which has the higher probability.

In operation S330, the state prediction data generator 232 may be configured to extract a particle having a weight which is greater than or equal to a given or predetermined weight and to perform a resampling operation. For example, a particle having a weight that is less than the given or predetermined weight may be removed, and only a particle having a weight which is greater than or equal to the given weight may remain. The state prediction data generator 232 may be configured to perform the resampling operation on the extracted particle depending on the weight, and to generate the posterior particle distribution.

As the SOH data Data_SOH are received, the state prediction data generator 232 may repeatedly perform operation S310 through operation S330; in this process, the state prediction data Data_P may be generated while correcting model coefficients of the health state model.

Returning to FIG. 8, in operation S230, the state prediction data generator 232 may be configured to generate the confidence interval based on the likelihood of the state prediction data Data_P generated in operation S320. The median and the standard deviation may be calculated from the likelihood of the state prediction data Data_P. The median may be defined as a value having a maximum value in the likelihood, and the standard deviation may be calculated under the assumption that the likelihood is a normal distribution.

The confidence interval may be generated based on the median and the standard deviation after setting a confidence level. For example, when the confidence level is set to 95%, the confidence interval may be an interval included in the number of standard deviations corresponding to 95% of the confidence level based on the median.

The state prediction data Data_P and the confidence interval generated by the state prediction data generator 232 may be provided to the correction signal generator 233 and the remaining life prediction unit 234, as shown for example in FIG. 7.

The correction signal generator 233 may be configured to receive the SOH data Data_SOH and to generate a correction signal Sig_Cor based on the state prediction data Data_P and the confidence interval.

In operation S240, the correction signal generator 233 may be configured to receive the SOH data Data_SOH from the state data generator 210 and to determine whether the SOH data Data_SOH is within the confidence interval of the state prediction data Data_P.

When the SOH data Data_SOH is within the confidence interval, operation S250 may be performed for the remaining life prediction unit 234 to calculate the remaining life based on the received state prediction data Data_P. In this case, the correction signal Sig_Cor may not be generated.

The remaining life of the battery may be an expected number of cycles until the available capacity of the battery is reduced from the current available capacity to the given or predetermined available capacity.

For example, the remaining life prediction unit 234 may calculate, as the remaining life, cycles that are necessary for the median of the state prediction data Data_P to reach a value of the SOH data Data_SOH corresponding to the given or predetermined available capacity.

For example, the remaining life prediction unit 234 may set the state of health of 80% to the critical point and may calculate an expected number of cycles until the median of the state prediction data reaches 0.8, as the remaining life.

In an embodiment, the remaining life prediction unit 234 may improve the accuracy of the remaining life calculated while correcting an error between the SOH data Data_SOH and the state prediction data Data_P generated based on the particle filter in the state prediction data generator 232 in operation S220.

When the SOH data Data_SOH is not within, or is outside of, the confidence interval, operation S260 may be performed such that the correction signal generator 233 generates the correction signal Sig_Cor. The correction signal generator 233 may generate the correction signal Sig_Cor to be transferred to the health state model generator 231.

The health state model generator 231 may be configured to receive the correction signal Sig_Cor. When the correction signal Sig_Cor is received, the health state model generator 231 may be configured to receive the past state data S_SOH which was stored in the state data storage unit 220 before the correction signal Sig_Cor was received and to regenerate or otherwise modify the health state model HSM. The health state model generator 231 may regenerate the health state model HSM by correcting the initial model coefficient using the least squares method LSM based on the received past state data S_SOH.

The health state model HSM regenerated by the health state model generator 231 may again be provided to the state prediction data generator 232, the state prediction data generator 232 may regenerate the state prediction data Data_P based on the regenerated health state model HSM, and the correction signal generator 233 may determine whether to generate the correction signal Sig_Cor based on the regenerated state prediction data Data_P and the SOH data Data_SOH.

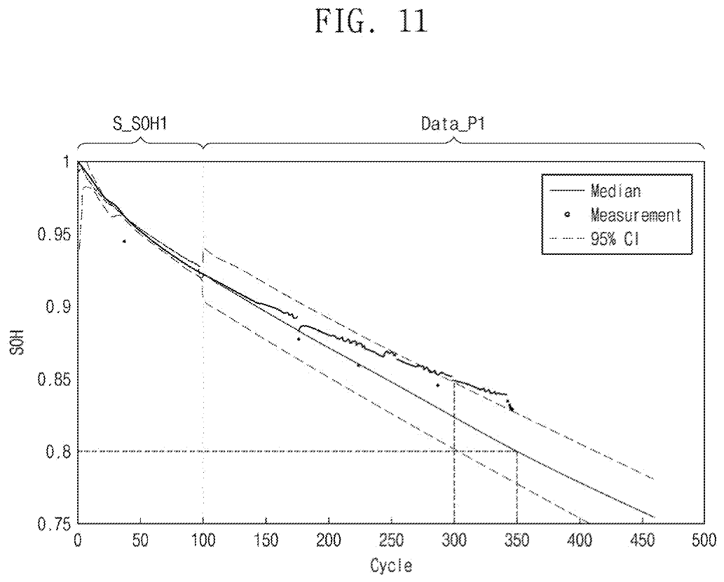

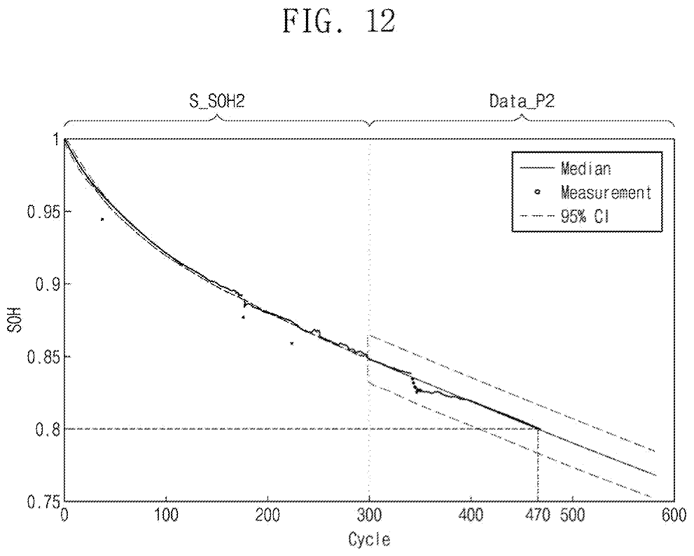

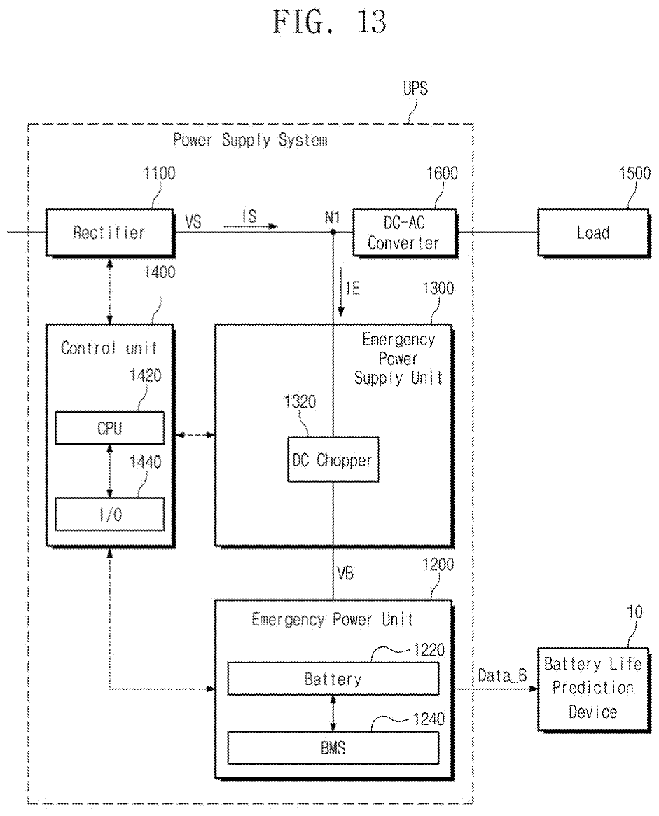

The battery life prediction system according to the present disclosure may be configured to generate the state prediction data based on the SOH data generated in real time. An example of an operation in which the battery life calculator 230 according to the present disclosure generates the state prediction data based on the past state data S_SOH and the real-time SOH data Data_SOH and calculates the remaining life is described in detail below with reference to FIGS. 11 and 12.

FIGS. 11 and 12 are graphs illustrating a health state model generated by the battery life calculator 230, a median of the state prediction data Data_P, a confidence interval CI, and the SOH data Data_SOH generated in real time.

Referring to FIG. 11, the battery life calculator 230 may receive first past state data S_SOH1 stored in the state data storage unit 220. The first past state data S_SOH1 may include the SOH data Data_SOH generated battery cycles from 0 to 100.

In the graph of FIG. 11, a solid state represents medians calculated from first state prediction data Data_P1, a dotted line represents a boundary of the confidence interval CI corresponding the confidence level of 95%, and irregularly marked dots or lines represent the SOH data Data_SOH generated by the state data generator 210.

The battery life calculator 230 may generate the health state model based on the first past state data S_SOH′. The battery life calculator 230 may apply the particle filter to the health state model and may generate the first state prediction data Data_P1 after the 100th battery cycle.

In battery cycles from one hundred to three hundred, the SOH data Data_SOH is within the confidence interval of the first state prediction data Data_P1. As such, until the 300th battery cycle is reached, the correction signal may not be generated by the battery life calculator 230, and the remaining life may be calculated based on the first state prediction data Data_P1.

For example, because the median of the first state prediction data Data_P1 reaches 0.8 at the 350th battery cycle, the battery life calculator 230 may calculate the number of battery cycles until the 350th battery cycle, as the remaining life at a previous time point of the 300th battery cycle.

The SOH data Data_SOH generated at the 300th battery cycle is not within, or is outside of, the confidence interval CI.

In a comparative example, when the remaining life is predicted using the previously generated health state model without generating the correction signal, a difference between the remaining life estimation value and an actual remaining life value may increase after the 300th battery cycle.

In contrast, according to embodiments, the correction signal generator may be configured to determine whether state-of-health data is included in a confidence interval of state prediction data, and to regenerate the health state model. For example, in an embodiment of the present disclosure, when the battery cycle reaches the 300th cycle, the battery life calculator 230 may generate a correction signal to regenerate a health state model. Accordingly, as a difference between a remaining life estimation value and an actual remaining life value decreases after the 300th battery cycle, the accuracy of remaining life prediction may be improved.

Referring to FIG. 12, when the battery cycle reaches the 300th cycle, the battery life calculator 230 may regenerate the health state model based on second past state data S_SOH2. The second past state data S_SOH2 may include the SOH data Data_SOH generated battery cycles from 0 to 300. The battery life calculator 230 may apply the particle filter to the regenerated health state model and may generate the second state prediction data Data_P2.

For example, because the median of the second state prediction data Data_P2 reaches 0.8 at the 470th battery cycle, the battery life calculator 230 may calculate the number of battery cycles, which remain until the 470th battery cycle, as the remaining life at a previous time point of the 470th battery cycle.

FIG. 13 is a block diagram illustrating an example where a risk evaluation device according to the present disclosure is applied to an uninterruptible power supply system.

Referring to FIG. 13, a risk evaluation device according to the present disclosure may be configured to evaluate a risk of a battery included in an uninterruptible power supply system UPS.

The uninterruptible power supply system UPS may include a first rectifier 1100, a first emergency power unit 1200, a first emergency power supply unit 1300, a control unit 1400, and a DC-AC converter 1600.

The first rectifier 1100 may include an insulated gate bipolar mode transistor (IGBT) rectifier, but the present disclosure is not limited thereto. The first rectifier 1100 may convert an AC power to a first DC power.

The first emergency power unit 1200 may be implemented with an emergency power supply source that supplies an emergency power to a load 1500 in the station blackout. The first emergency power unit 1200 may include a first battery 1220 and a first battery management system (BMS) 1240.

The first emergency power supply unit 1300 may form a path through which an emergency power is supplied from the first emergency power unit 1200 to the load 1500 in the blackout state. For example, the blackout state may refer a state where the first rectifier 1100 does not output the first DC power. The first emergency power supply unit 1300 may include a first DC chopper 1320.

A first connection node N1 may refer a point where an output terminal of the first rectifier 1100 and a first terminal of the first emergency power supply unit 1300 are connected. A second connection node N2 that is different from the first connection node N1 may refer to a point where a second terminal of the first emergency power supply unit 1300 and the first emergency power unit 1200 are connected. Voltages of the first connection node N1 and the second connection node N2 may be identical at a specific time point; however, the first connection node N1 and the second connection node N2 are different nodes that are physically separated from each other.

The control unit 1400 may control the first rectifier 1100, the first emergency power unit 1200, and the first emergency power supply unit 1300. The control unit 1400 may include a CPU 1420 and an input/output (I/O) terminal 1440.

In a normal state, the control unit 1400 may turn on the first DC chopper 1320. In this case, the first DC chopper 1320 may step up a voltage VS of a first DC power source such that the first battery 1220 is charged to a battery voltage VB in the floating charge manner. For example, the normal state may refer to a state where the first rectifier 1100 outputs the first DC power.

When the first DC chopper 1320 operates abnormally in the normal state, the control unit 1400 may turn off the first DC chopper 1320.

In the blackout state, the control unit 1400 may turned off the first rectifier 1100 and may maintain the turn-on state of the first DC chopper 1320. In this case, the first DC chopper 1320 may form a path through which a second DC power is supplied to the first connection node N1. For example, the second DC power may refer to a power that is supplied from the first battery 1220 to the load 1500 through the first DC chopper 1320. The first battery 1220 may supply the second DC power by stepping down, at the first DC chopper 1320, the battery voltage VB of the first battery 1220 so as to be applied to the first connection node N1.

When the first DC chopper 1320 operates abnormally in the blackout state, the control unit 1400 may turn off the first rectifier 1100 and the first DC chopper 1320.

The DC-AC converter 1600 may be provided to be connected with the first connection node N1. The DC-AC converter 1600 may convert the first DC power from the first rectifier 1100 to the AC power.

In an application example, the battery life prediction device 10 according to the present disclosure may be configured to collect the battery information Data_B from the first BMS 1240 included in the uninterruptible power supply system and to calculate the remaining life of the first battery 1220.

According to an embodiment of the present disclosure, a device that predicts a remaining life of a battery according to a current battery state more accurately is provided.

According to an embodiment of the present disclosure, a method of predicting a remaining life of a battery according to a current battery state more accurately is provided.

While the present disclosure has been described with reference to embodiments thereof, it will be apparent to those of ordinary skill in the art that various changes and modifications may be made thereto without departing from the spirit and scope of the present disclosure as set forth in the following claims.

1. A battery life prediction device comprising:
a state data generator configured to receive information about a battery in real time and to generate state-of-health data;
a state data storage configured to store the state-of-health data generated by the state data generator, and to store past state data which is generated based on the state-of-health data; and
a battery life calculator configured to:
generate a health state model comprising a formula which indicates an aging trend of the battery based on the past state data,
generate state prediction data based on the state-of-health data generated by the state data generator using the health state model,
determine whether to modify the health state model based on the state prediction data and the state-of-health data, and
calculate a remaining life of the battery,
wherein to generate the health state model, the battery life calculator is further configured to:
generate an initial model comprising a non-linear function which includes a model coefficient,
determine an initial model coefficient by correcting the model coefficient using a least squares approximation based on the initial model and the past state data, and
generate the health state model based on the initial model coefficient and the initial model.

2. The battery life prediction device of claim 1, wherein the state data generator is further configured to generate the state-of-health data based on output voltage data and output current data of the battery using an electrical equivalent circuit model of the battery.

3. The battery life prediction device of claim 2, wherein the state data generator is further configured to generate the state-of-health data based on the output voltage data and the output current data using a dual extended Kalman filter.

4. The battery life prediction device of claim 3, wherein the state data generator comprises:
a state data calculator configured to generate the state-of-health data and state-of-charge data using the dual extended Kalman filter; and
a battery cycle calculator configured to generate battery cycle data based on the state-of-charge data, and
wherein the battery cycle data and the state-of-health data is stored in the state data storage as the past state data.

5. The battery life prediction device of claim 2, wherein the electrical equivalent circuit model comprises a Thevenin equivalent circuit model of the battery.

6. The battery life prediction device of claim 1,
wherein the battery life calculator comprises:
a health state model generator configured to generate the health state model using the least squares approximation based on the past state data;
a state prediction data generator configured to apply a particle filter to the health state model and to generate the state prediction data according to a likelihood function based on the state-of-health data;
a correction signal generator configured to generate a correction signal based on the state prediction data and the state-of-health data; and
a remaining life prediction unit configured to calculate the remaining life of the battery based on the state prediction data,
wherein the state prediction data generator is configured to generate a confidence interval based on a likelihood corresponding to the state prediction data, and
wherein the correction signal generator is further configured to generate the correction signal based on the state-of-health data being outside of the confidence interval.

7. The battery life prediction device of claim 6, wherein the health state model generator is further configured to:
receive the correction signal, and
based on the correction signal being received, modify the health state model by correcting the initial model coefficient based on the past state data stored in the state data storage before a time point at which the correction signal was received.

8. The battery life prediction device of claim 7, wherein the health state model generator is further configured to modify the health state model by correcting the initial model coefficient using the least squares approximation based on the stored past state data.

9. The battery life prediction device of claim 6, wherein based on the state-of-health data being within the confidence interval, the battery life calculator is further configured to calculate the remaining life of the battery based on the state prediction data.

10. A method of predicting a battery life, the method comprising:
collecting information about a battery in real time to generate state-of-health data;
generating past state data by storing the state-of-health data;
generating a health state model comprising a formula which indicates an aging trend of the battery based on the past state data;
generating state prediction data based on the state-of-health data using the health state model;
determining whether to modify the health state model based on the state prediction data and the state-of-health data; and
calculating a remaining life of the battery based on the state prediction data.

11. The method of claim 10, wherein the state-of-health data is generated based on output voltage data and output current data of the battery using an electrical equivalent circuit model of the battery.

12. The method of claim 11, wherein the state-of-health data is generated based on the output voltage data and the output current data using a dual extended Kalman filter.

13. The method of claim 12, wherein the electrical equivalent circuit model includes a Thevenin equivalent circuit model of the battery.

14. The method of claim 10, wherein the generating of the health state model comprises:
generating an initial model comprising a non-linear function which includes a model coefficient;
determining an initial model coefficient by correcting the model coefficient using a least squares approximation based on the initial model and the past state data; and
generating the health state model based on the initial model coefficient and the initial model.

15. The method of claim 10, wherein the generating of the state prediction data comprises applying a particle filter to the health state model to generate the state prediction data according to a likelihood function based on the state-of-health data.

16. The method of claim 15, wherein the determining whether to modify the health state model includes:
generating a confidence interval based on a likelihood corresponding to the state prediction data;
based on the state-of-health data being outside of the confidence interval, generating a correction signal; and
modifying the health state model based on the past state data stored before a time point at which the correction signal was generated.

17. The method of claim 16, wherein based on the health state model being regenerated, the method further comprises:
modifying the state prediction data using the modified health state model; and
calculating the remaining life of the battery based on the modified state prediction data.

18. A battery life prediction system comprising:
a battery including a battery pack;
a data measurement unit configured to measure information about the battery, and to generate sensing data including output voltage data and output current data; and
a battery life prediction device configured to generate state prediction data based on the sensing data, and to calculate a remaining life of the battery,
wherein the battery life prediction device comprises:
a state data generator configured to receive the sensing data in real time and to generate state-of-health data;
a state data store unit configured to store the state-of-health data generated by the state data generator and to generate past state data; and
a battery life calculator configured to:
generate a health state model indicating an aging trend of the battery in a formula type based on the past state data,
generate the state prediction data based on the state-of-health data generated by the state data generator by using the health state model,
determine whether to regenerate the health state model based on the state prediction data and the state-of-health data, and
calculate the remaining life of the battery,
wherein to generate the health state model, the battery life calculator is further configured to:
generate an initial model comprising a non-linear function which includes a model coefficient; and
determine an initial model coefficient by correcting the model coefficient using a least squares approximation based on the initial model and the past state data; and
generate the health state model based on the initial model coefficient and the initial model.

19. The battery life prediction system of claim 18, wherein the state data generator is further configured to generate the state-of-health data based on the output voltage data and the output current data of the battery using an electrical equivalent circuit model of the battery.

20. The battery life prediction system of claim 18, wherein the battery life calculator comprises:
a health state model generator configured to generate the health state model using the least squares approximation based on the past state data;
a state prediction data generator configured to apply a particle filter to the health state model and to generate the state prediction data according to a likelihood function based on the state-of-health data;
a correction signal generator configured to generate a correction signal based on the state prediction data and the state-of-health data; and
a remaining life prediction unit configured to calculate the remaining life of the battery based on the state prediction data,
wherein the state prediction data generator is configured to generate a confidence interval based on a likelihood corresponding to the state prediction data, and
wherein the correction signal generator is further configured to generate the correction signal based on the state-of-health data being outside of the confidence interval.

21-23. (canceled)
